(19) United States
(12) Patent Application Publication
(10) Pub. No.: US 2020/0321259 A1
(43) Pub. Date: Oct. 8, 2020

(54) SEMICONDUCTOR PACKAGE STRUCTURE

(71) Applicant: Powertech Technology Inc., Hsinchu County (TW)

(72) Inventors: Chih-Yen Su, Hsinchu County (TW); Chun-Te Lin, Hsinchu County (TW)

(73) Assignee: Powertech Technology Inc., Hsinchu County (TW)

(21) Appl. No.: 16/417,671

(22) Filed: May 21, 2019

(30) Foreign Application Priority Data
Apr. 8, 2019 (TW) 108112107

(51) Int. Cl. H01L 23/31; H01L 23/00

(52) U.S. Cl. CPC H01L 23/3128; H01L 24/17; H01L 23/3114

(57) ABSTRACT

A semiconductor package structure includes a substrate, a chip, and an encapsulant. The chip is disposed on the substrate. The encapsulant is disposed on the substrate and covers the chip. The encapsulant has a top surface away from the substrate and at least one protruding strip protruding from the top surface.

### CROSS-REFERENCE TO RELATED APPLICATION

This application claims the priority benefit of Taiwan application Ser. No. 108112107, filed on Apr. 8, 2019. The entirety of the above-mentioned patent application is hereby incorporated by reference herein and made a part of this specification.

### BACKGROUND

### Field of the Disclosure

The present disclosure relates to a package structure, and more particularly to a semiconductor package structure.

### Description of Related Art

FIG. 1 is a schematic perspective view of a conventional semiconductor package structure, please refer to FIG. 1. A conventional semiconductor package structure 10 includes a chip 20, an encapsulant 30, and a substrate 40. The chip 20 is electrically connected to the substrate 40, and the encapsulant 30 covers the chip 20 such that the chip 20 is stably disposed on the substrate 40. Solder balls are disposed at the bottom of the substrate 40 such that the substrate 40 is electrically connected to other electronic components.

In general, the encapsulant 30 is typically made of Epoxy Molding Compounds (EMC), which is a thermosetting encapsulant material (colloid) commonly used in IC packaging processes, and generates cross-linking reaction as the temperature increases in the filling process of the encapsulant 30. When the cross-linking reaction proceeds to a certain stage, the encapsulant 30 will be cured, rendering the product better mechanical properties and stability. However, the encapsulant 30 is often not fully cured after the encapsulant 30 is completely filled. Therefore, a post-mold cure process is often performed to promote complete curing of the encapsulant 30. Baking is one of the common post-mold cure methods, through which the encapsulant 30 is cooled after it is fully cured. In the process, since the volume of the encapsulant 30 may shrink due to the cross-linking reaction, and the coefficients of thermal expansion of various components are different, residual stress is generated under the influence of temperature change, which generates a corresponding displacement deformation and thus a warpage is caused as shown in FIG. 1. If the amount of deformation is too large, it may cause damage to the electronic components and increase the difficulty of the manufacturing process.

At present, the way to prevent the warpage is to select a combination of components with the materials of which the coefficients of thermal expansion match each other. However, when the number of components is more complicated, there is limitation in making adjustment to the coefficients of thermal expansion of the material of components.

### SUMMARY

The present disclosure provides a semiconductor package structure which can reduce warpage caused by temperature changes.

The semiconductor package structure of the present disclosure includes a substrate, a chip and an encapsulant. The chip is disposed on the substrate. The encapsulant is disposed on the substrate and covers the chip. The encapsulant has a top surface away from the substrate and at least one protruding strip protruding from the top surface.

In an embodiment of the disclosure, the shape of the at least one protruding strip is a rectangular column.

In an embodiment of the disclosure, the at least one protruding strip includes a plurality of protruding strips, and the protruding strips are arranged in parallel.

In an embodiment of the present disclosure, the at least one protruding strip includes a first protruding strip and a second protruding strip. The first protruding strip is arranged along a first direction, and the second protruding strip is arranged along a second direction, and the first protruding strip is interlaced with the second protruding strip.

In an embodiment of the disclosure, the first direction is perpendicular to the second direction.

In an embodiment of the disclosure, the at least one protruding strip includes a plurality of protruding strips arranged along a straight line and separated from each other.

In an embodiment of the disclosure, an orthogonal projection of the at least one protruding strip relative to the substrate does not overlap an orthogonal projection of the chip relative to the substrate.

In an embodiment of the disclosure, an orthogonal projection of the at least one protruding strip relative to the substrate at least partially overlaps an orthogonal projection of the chip relative to the substrate.

In an embodiment of the disclosure, the minimum distance between the at least one protruding strip and the edge of the top surface of the encapsulant is between 0.5 mm and 3 mm.

In an embodiment of the disclosure, the height of the at least one protruding strip is between 0.01 mm and 0.1 mm, and the width of the at least one protruding strip is between 0.5 mm and 3 mm.

Based on the above, in the semiconductor package structure of the present disclosure, the encapsulant has a protruding strip protruding from the top surface. The designer can dispose the protruding strip on the top surface along the possible warping direction (but not limited to this direction) of the semiconductor package structure. In this manner, when the semiconductor package structure is subjected to a temperature change, the protruding strip can enhance the structural strength of the encapsulant in the warping direction, thereby effectively reducing the probability that the encapsulant is bent in the warping direction.

In order to make the aforementioned features and advantages of the disclosure more comprehensible, embodiments accompanying figures are described in detail below.

### BRIEF DESCRIPTION OF THE DRAWINGS

FIG. 1 is a schematic perspective view of a conventional semiconductor package structure.

FIG. 2 is a schematic perspective view of a semiconductor package structure according to an embodiment of the disclosure.

FIG. 3 is a schematic cross-sectional view of a cross section taken along line A-A of FIG. 2.

FIG. 4A is a schematic top view of an encapsulant of FIG. 3.

FIG. 4B-FIG 4E are schematic top views of an encapsulant in a semiconductor package structure according to other embodiments of the present disclosure.

### DESCRIPTION OF EMBODIMENTS

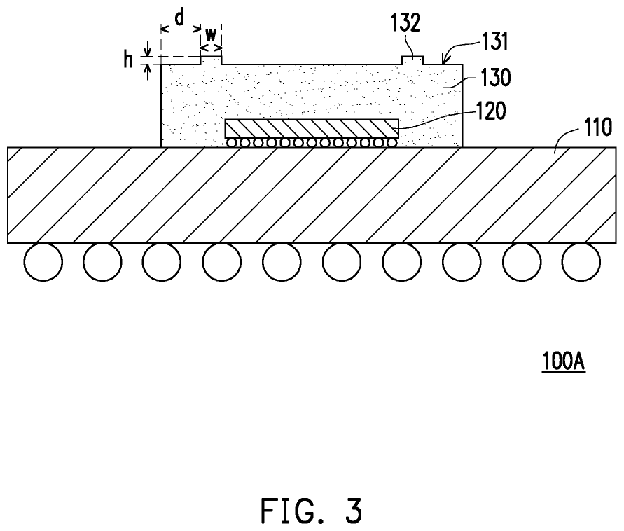

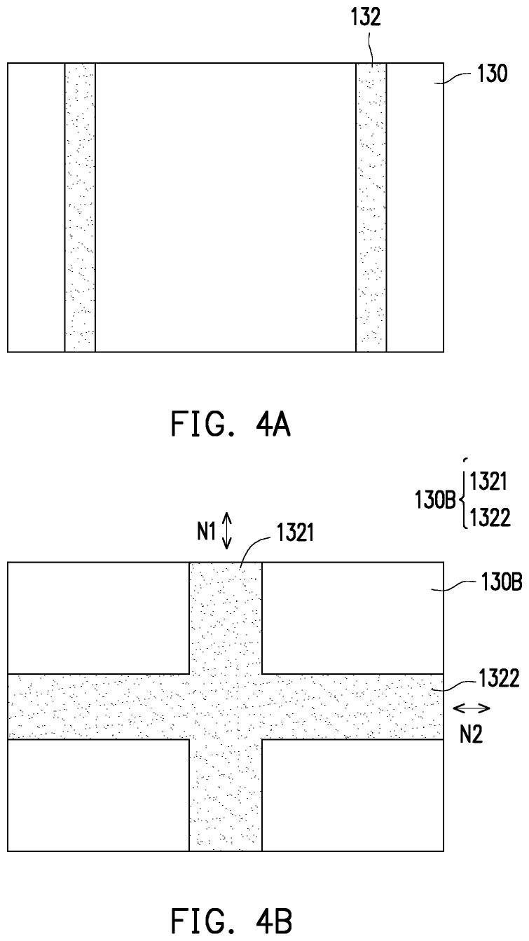

FIG. 2 is a schematic perspective view of a semiconductor package structure according to an embodiment of the disclosure. FIG. 3 is a schematic cross-sectional view of a cross section taken along line A-A of FIG. 2. Referring to FIG. 2 and FIG. 3, a semiconductor package structure 100A of the present embodiment includes a substrate 110, a chip 120 (FIG. 2) and an encapsulant 130. In this embodiment, the substrate 110 is represented by a single layer structure only. In fact, the substrate 110 may be a combination of a plurality of layers, but the disclosure is not limited thereto. In the present embodiment, the encapsulant 130 is, for example, an epoxy molding compound (EMC), but the disclosure is not limited thereto.

It should be noted that the semiconductor package structure 100A illustrated in FIG. 2 and FIG. 3 only schematically shows the relative positions of the components, and is for reference only, and the actual number and dimension proportion thereof may be not similar to the illustration shown in FIG. 2 and FIG. 3.

Referring to FIG. 3, the chip 120 is disposed on the substrate 110 and electrically connected to the substrate 110 by a plurality of solder balls. In this embodiment, a plurality of solder balls are also disposed at the bottom of the substrate 110 such that the substrate 110 is electrically connected to other electronic components. However, in other embodiments, the manner in which the chip 120 and the substrate 110 or the substrate 110 and other electronic components are electrically connected is not limited to the above.

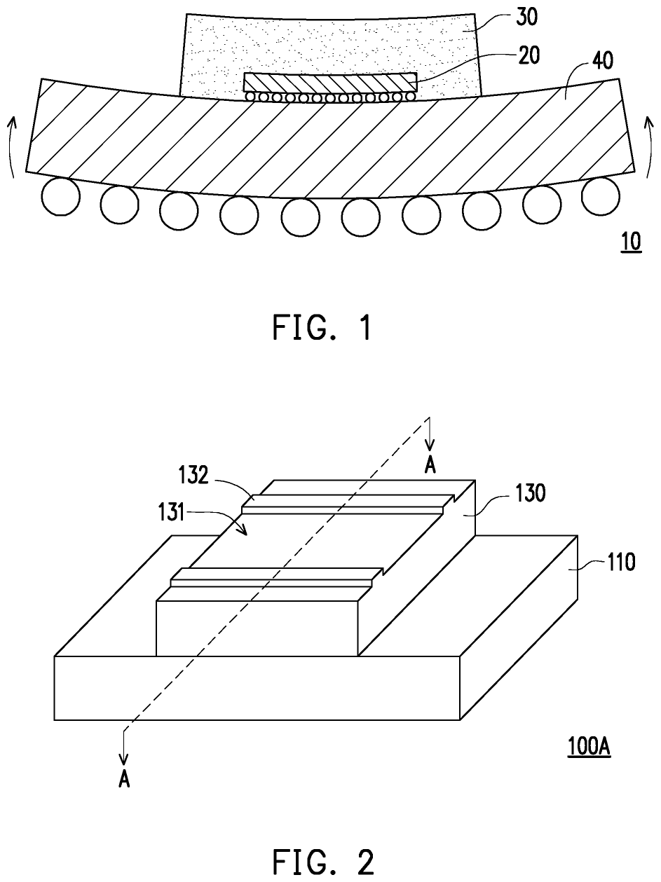

In the present embodiment, the encapsulant 130 is disposed on the substrate 110 and covers the chip 120. The encapsulant 130 has a top surface 131 away from the substrate 110. In order to prevent the warpage from being caused to the semiconductor package structure 100 at the stress concentrating position when the semiconductor package structure 100 in FIG. 1 is heated, as compared with the encapsulant 30 used for the conventional semiconductor package structure 100 of FIG. 1, the encapsulant 130 in this embodiment has a protruding strip 132, and the protruding strip 132 protrudes from the top surface 131.

Since the designer knows the coefficients of thermal expansion of each material of the semiconductor package structure 100A and/or the material and thickness of the plurality of layers of the substrate 110, the possible warping direction of the semiconductor package structure when no protruding strip 132 is provided can be inferred in advance. Thereafter, the designer can design the protruding strip 132 on the top surface 131 along the warping direction. For example, if the semiconductor package structure is warped in the left-right direction of FIG. 2, the designer can arrange the protruding strip 132 on the top surface 131 along the left-right direction as shown in FIG. 2.

In the present embodiment, in order to facilitate the manufacturing process, the shape of the protruding strip 132 is a rectangular column. According to the following equation (1) of the moment of inertia of the rectangular cross-section, it can be acquired that adjusting the height (h) can most influence the moment of inertia (I) of the rectangular cross-section, so increasing the height (h) of the encapsulant 130 can increase the strength of warpage resistance of the semiconductor package structure. However, in order to save the cost for the material of the encapsulant 130, it is not required to increase the overall height of the encapsulant 130, by only increasing the protruding strip 132 along the warping direction (at least at the highest and lowest positions of the warped shape), it is possible to increase the height of a partial position on the top surface 131 of the encapsulant 130, such that the amount of warpage can be decreased and the structure can be designed with lower cost.

1= 1/12×b×h³ equation (1)

In the present embodiment, by increasing the height at the position where the stress generated by the semiconductor package structure 100A is concentrated during heating process to form the protruding strip 132, the position of the semiconductor package structure 100A having the protruding strip 132 has a higher warping-resisting strength, thereby resisting the warpage of the semiconductor package structure 100A during the heating process. As a result, when the semiconductor package structure 100A is subjected to temperature changes, the protruding strip 132 can increase the structural strength and bending resistance of the encapsulant 130 in the warping direction (for example, the left-right direction of FIG. 2), thereby effectively reducing the probability of the encapsulant 130 being bent in the warping direction, thus reducing the degree of warpage of the overall semiconductor package structure 100A. Certainly, in other embodiments, the protruding strip 132 may not be disposed along the warping direction or not only along the warping direction, the disclosure provides no limitation thereto.

Certainly, in other embodiments, the shape of the protruding strip 132 may also be a triangular column, a semi-circular column, a trapezoid column or a column with an irregular shape. On this occasion, it is required to select a corresponding equation for the moment of inertia of cross-section of other shapes, and the disclosure provides no limitation thereto.

Further, as shown in FIG. 3, in the present embodiment, the minimum distance d between the protruding strip 132 and the edge of the top surface of the encapsulant 130 is preferably 0.5 mm. However, in other embodiments, the minimum distance d between the protruding strip 132 and the edge of the top surface of the encapsulant 130 may also be between 0.5 mm and 3 mm.

In the present embodiment, the height h of the protruding strip 132 is between 0.01 mm and 0.1 mm, and the width w of the protruding strip 132 is between 0.5 mm and 3 mm.

In the present embodiment, the orthogonal projection of the protruding strip 132 relative to the substrate 110 does not overlap the orthogonal projection of the chip 120 relative to the substrate 110. However, in other embodiments, the orthogonal projection of the protruding strip 132 relative to the substrate 110 at least partially overlaps the orthogonal projection of the chip 120 relative to the substrate 110. That is, the protruding strip 132 is formed on the top surface 131 of the encapsulant 130 without having to avoid the chip 120.

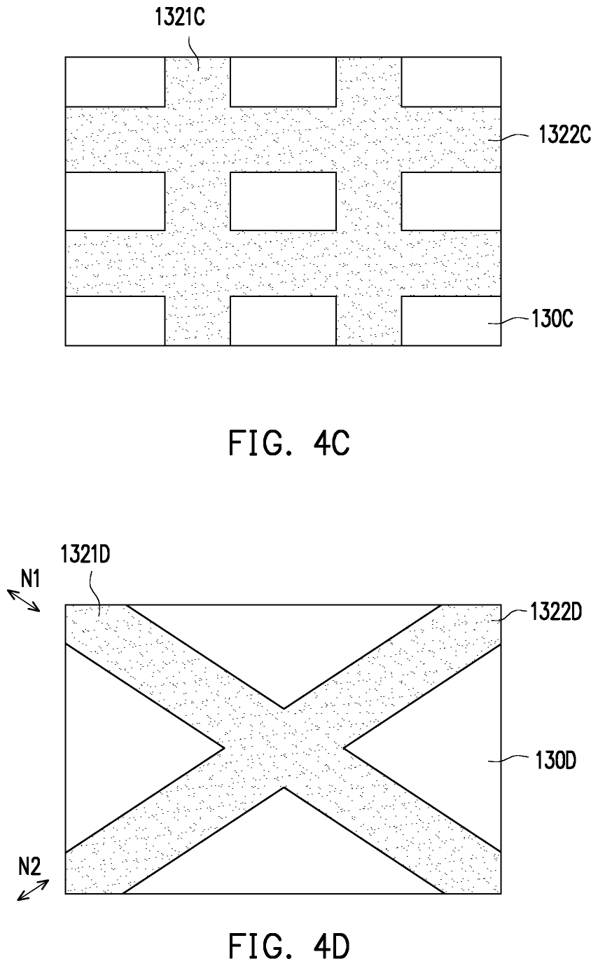

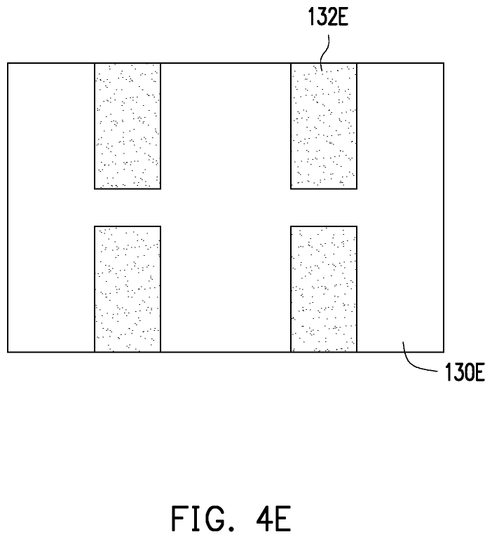

FIG. 4A is a schematic top view of the encapsulant of FIG. 3. Referring to FIG. 4A, in the embodiment, the number of the at least one protruding strip 132 is two, and the protruding strips 132 are arranged in parallel. However, in other embodiments, the number of the protruding strips 132 may also be one or two or more, the disclosure provides no limitation thereto.

Other embodiments are listed below for illustration. It should noted that the following embodiments use the same reference numerals and parts of content of the above-mentioned embodiments, and the same reference numerals are used to refer to the same or similar elements, and the description of the same technical content is omitted. For the description of the omitted portions, reference may be made to the foregoing embodiments, and no repetition is incorporated in the following embodiments.

FIG. 4B-FIG. 4E are schematic top views of an encapsulant in a semiconductor package structure according to other embodiments of the present disclosure. Referring to FIG. 4B, in the embodiment, the encapsulant 130B is slightly different from the encapsulant 130 of FIG. 4A, and the difference is that in the embodiment, at least one protruding strip 132B of the encapsulant 130B includes a first protruding strip 1321 and a second protruding strip 1322. The first protruding strip 1321 is arranged along a first direction N1, the second protruding strip 1322 is arranged along a second direction N2, and the first protruding strip 1321 and the second protruding strip 1322 are interlaced.

In this embodiment, the first direction N1 is perpendicular to the second direction N2 such that the first protruding strip 1321 and the second protruding strip 1322 are in a cross shape.

Referring to FIG. 4C, the encapsulant 130C in this embodiment is slightly different from the encapsulant 130B in FIG. 4B, and the difference is that in the embodiment, the number of the first protruding strip 1321C of the encapsulant 130C is two and the number of the second protruding strip 1322C is two, such that the first protruding strips 1321C and the second protruding strips 1322C are in “#” shape.

In other embodiments, the number of the first protruding strips 1321C and the second protruding strips 1322C may also be two or more, respectively; and the number of the first protruding strips 1321C and the second protruding strips 1322C may also be different, the disclosure provides no limitation thereto.

Referring to FIG. 4D, the encapsulant 130D in this embodiment is slightly different from the encapsulant 130B in FIG. 4B, and the difference is that in the embodiment, the first direction N1 is not perpendicular to the second direction N2, such that the first protruding strip 1321D and the second protruding strip 1322D are in an X shape.

In this embodiment, the number of the first protruding strips 1321D and the second protruding strips 1322D are respectively one, but in other embodiments, the number of the first protruding strips 1321D and the second protruding strips 1322D may also be one or more, respectively, such that the plurality of first protruding strips 1321D and the second protruding strips 1322D are in rhombus shapes.

Referring to FIG. 4E, the encapsulant 130E in this embodiment is slightly different from the encapsulant 130A of FIG. 4A, and the difference is that in this embodiment, the plurality of protruding strips 132E of the encapsulant 130E are arranged in a straight line and separated from each other. That is, the plurality of protruding strips 132E are block-shaped and discontinuous from each other.

The above design can increase the structural strength and bending resistance of the encapsulant through the protruding strip, thereby effectively reducing the probability of warpage of the encapsulant, and thus reducing the degree of warpage of the substrate and the chip, so that the overall semiconductor package structure has a good structural strength.

In summary, in the semiconductor package structure of the present disclosure, the encapsulant has a protruding strip protruding from the top surface. The designer can dispose the protruding strip on the top surface along the possible warping direction of the semiconductor package structure. In this manner, when the semiconductor package structure is subjected to a temperature change, the protruding strip can enhance the structural strength of the encapsulant in the warping direction, thereby effectively reducing the probability that the encapsulant is bent in the warping direction. In addition, since it only requires the designer to provide the protruding strip at a partial position (for example, the highest and lowest positions that may be warped) on the top surface of the encapsulant to reduce the height difference between the highest and lowest heights when warpage is generated and reduce the amount of warpage, there is no need to increase the height of the overall encapsulant to increase the structural strength. Accordingly, the above design has a lower material cost for the encapsulant.

Although the disclosure has been disclosed by the above embodiments, the embodiments are not intended to limit the disclosure. It will be apparent to those skilled in the art that various modifications and variations can be made to the structure of the disclosure without departing from the scope or spirit of the disclosure. Therefore, the protecting range of the disclosure falls in the appended claims.

1. A semiconductor package structure, comprising:
a substrate;
a chip, disposed on the substrate; and
an encapsulant, disposed on the substrate and covering the chip, the encapsulant having a top surface away from the substrate and at least one protruding strip protruding from the top surface.

2. The semiconductor package structure according to claim 1, wherein a shape of the at least one protruding strip is a rectangular column.

3. The semiconductor package structure according to claim 1, wherein the at least one protruding strip comprises a plurality of protruding strips, the protruding strips are arranged in parallel.

4. The semiconductor package structure according to claim 1, wherein the at least one protruding strip comprises a first protruding strip and a second protruding strip, the first protruding strip is arranged along a first direction, the second protruding strip is arranged along a second direction, and the first protruding strip is interlaced with the second protruding strip.

5. The semiconductor package structure according to claim 3, wherein the first direction is perpendicular to the second direction.

6. The semiconductor package structure according to claim 1, wherein the at least one protruding strip comprises a plurality of protruding strips arranged along a straight line and separated from each other.

7. The semiconductor package structure according to claim 1, wherein an orthogonal projection of the at least one protruding strip relative to the substrate does not overlap an orthogonal projection of the chip relative to the substrate.

8. The semiconductor package structure according to claim 1, wherein an orthogonal projection of the at least one protruding strip relative to the substrate at least partially overlaps an orthogonal projection of the chip relative to the substrate.

9. The semiconductor package structure according to claim 1, wherein a minimum distance between the at least one protruding strip and an edge of the top surface of the encapsulant is between 0.5 mm and 3 mm.

10. The semiconductor package structure according to claim 1, wherein a height of the at least one protruding strip is between 0.01 mm and 0.1 mm, and a width of the at least one protruding strip is between 0.5 mm and 3 mm.
